(19) United States
(12) Patent Application Publication
(10) Pub. No.: US 2025/0309853 A1
(43) Pub. Date: Oct. 2, 2025

(54) MULTILAYERED BRANCHING FILTER

(71) Applicant: TDK Corporation, Tokyo (JP)

(72) Inventor: Jun NAKATSUTSUMI, Tokyo (JP)

(73) Assignee: TDK Corporation, Tokyo (JP)

(21) Appl. No.: 19/086,334

(22) Filed: Mar. 21, 2025

(30) Foreign Application Priority Data
Mar. 26, 2024 (JP) 2024-050272

(51) Int. Cl. H03H 7/01; H03H 1/00

(52) U.S. Cl. CPC H03H 7/0115; H03H 1/00; H03H 2001/0085

(57) ABSTRACT

A stack of a branching filter includes a first region and a second region, and includes a first structure body that is arranged in a vicinity of a boundary between the first region and the second region and is connected to the ground. The first structure body includes a plurality of first sub structure bodies that are stacked in a direction parallel to a stacking direction of a plurality of dielectric layers. Each of the plurality of first sub structure bodies include a plurality of first through holes and a first conductor layer that connects the plurality of first through holes. A first inductor is arranged in the second region, and is connected to the first structure body.

### CROSS-REFERENCE TO RELATED APPLICATION

This application claims the benefit of Japanese Priority Patent Application No. 2024-050272 filed on Mar. 26, 2024, the entire contents of which are incorporated herein by reference.

### BACKGROUND

The disclosure relates to a branching filter that separates a plurality of signals having frequencies different from each other.

In a compact mobile communication apparatus, there has widely been used a configuration in which an antenna commonly used for a plurality of applications for different systems and frequency bands in use is provided and a plurality of signals transmitted and received by the antenna are separated by using a branching filter.

In general, a branching filter that separates a first signal having a frequency in a first frequency band and a second signal having a frequency in a second frequency band higher than the first frequency band includes a common port, a first signal port, a second signal port, a first filter provided to a first signal path from the common port to the first signal port, and a second filter provided to a second signal path from the common port to the second signal port.

In recent years, the market has been demanding a smaller, more space-saving mobile communication apparatus, and there is also a demand for a smaller branching filter to be used in the communication apparatus. As a branching filter suitable for size reduction, there has been known a branching filter using a stack including a plurality of dielectric layers being stacked and a plurality of conductor layers.

WO 2019/244481 A1 discloses a stacked composite filter device including a stack formed by stacking dielectrics, a first filter arranged in a first region, a second filter arranged in a second region, and a conductive member arranged in a region of the first region that is adjacent to the second region. The conductive member extends in a stacking direction. One end of the conductive member is grounded, and the other end of the conductive member is connected to an inductor of the first filter.

In recent years, the market has been demanding a smaller, more space-saving mobile communication apparatus, and there is also a demand for a smaller branching filter to be used in the communication apparatus. However, when the branching filter is reduced in size, there arises a problem that isolation between the first filter and the second filter is degraded.

In WO 2019/244481 A1, the conductive member having a columnar shape shields a space between the first filter and the second filter. However, when the branching filter is further reduced in size, the conductive member having a columnar shape may be insufficient.

### SUMMARY

A multilayered branching filter according to one embodiment of the disclosure includes a common terminal, a first signal terminal, a second signal terminal, a first path connecting the common terminal and the first signal terminal to each other, a second path connecting the common terminal and the second signal terminal to each other, a first inductor provided between the common terminal and the second signal terminal in a circuit configuration, and a stack for integrating the common terminal, the first signal terminal, the second signal terminal, the first path, the second path, and the first inductor, the stack including a plurality of dielectric layers being stacked. The first path is configured to selectively cause a signal having a frequency within a first passband to pass. The second path is configured to selectively cause a signal having a frequency within a second passband to pass, the second passband being different from the first passband.

The stack further includes a first region and a second region that are adjacent within the stack, and includes a first structure body that is arranged in a vicinity of a boundary between the first region and the second region and is connected to a ground. The first structure body includes a plurality of first sub structure bodies that are stacked in a direction parallel to a stacking direction of the plurality of dielectric layers. Each of the plurality of first sub structure bodies includes a plurality of first through holes and a first conductor layer that connects the plurality of first through holes. The first inductor is arranged in the second region, and is connected to the first structure body.

Other and further objects, features, and advantages of the disclosure will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a circuit diagram showing a circuit configuration of a multilayered branching filter according to the exemplary embodiment of the disclosure.

FIG. 2 is a perspective view showing an external appearance of the multilayered branching filter according to the exemplary embodiment of the disclosure.

FIG. 3A to FIG. 3C are explanatory diagrams showing respective patterned surfaces of first to third dielectric layers of a stack of the multilayered branching filter according to the exemplary embodiment of the disclosure.

FIG. 4A to FIG. 4C are explanatory diagrams showing respective patterned surfaces of fourth to sixth dielectric layers of the stack of the multilayered branching filter according to the exemplary embodiment of the disclosure.

FIG. 5A to FIG. 5C are explanatory diagrams showing respective patterned surfaces of seventh to ninth dielectric layers of the stack of the multilayered branching filter according to the exemplary embodiment of the disclosure.

FIG. 6A to FIG. 6C are explanatory diagrams showing respective patterned surfaces of tenth to twelfth dielectric layers of the stack of the multilayered branching filter according to the exemplary embodiment of the disclosure.

FIG. 7A to FIG. 7C are explanatory diagrams showing respective patterned surfaces of thirteenth to fifteenth dielectric layers of the stack of the multilayered branching filter according to the exemplary embodiment of the disclosure.

FIG. 8A to FIG. 8C are explanatory diagrams showing respective patterned surfaces of sixteenth to eighteenth layers of the stack of the multilayered branching filter according to the exemplary embodiment of the disclosure.

FIG. 9A to FIG. 9C are explanatory diagrams showing respective patterned surfaces of nineteenth to twenty-first layers of the stack of the multilayered branching filter according to the exemplary embodiment of the disclosure.

FIG. 10A to FIG. 10C are explanatory diagrams showing respective patterned surfaces of twenty-second to twenty-fourth layers of the stack of the multilayered branching filter according to the exemplary embodiment of the disclosure.

FIG. 11A and FIG. 11B are explanatory diagrams showing respective patterned surfaces of twenty-fifth and twenty-sixth layers of the stack of the multilayered branching filter according to the exemplary embodiment of the disclosure.

FIG. 12 is a perspective view showing an internal structure of the stack of the multilayered branching filter according to the exemplary embodiment of the disclosure.

FIG. 13 is a plan view showing a part of the internal structure of the stack of the multilayered branching filter according to the exemplary embodiment of the disclosure.

FIG. 14 is a characteristic chart showing frequency characteristics of isolation between a first signal terminal and a third signal terminal, which are acquired by simulation.

FIG. 15 is a characteristic chart showing frequency characteristics of isolation between a second signal terminal and the third signal terminal, which are acquired by simulation.

### DETAILED DESCRIPTION

An object of the disclosure is to provide a branching filter that can secure isolation between two regions.

In the following, some example embodiments and modification examples of the disclosure will be described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

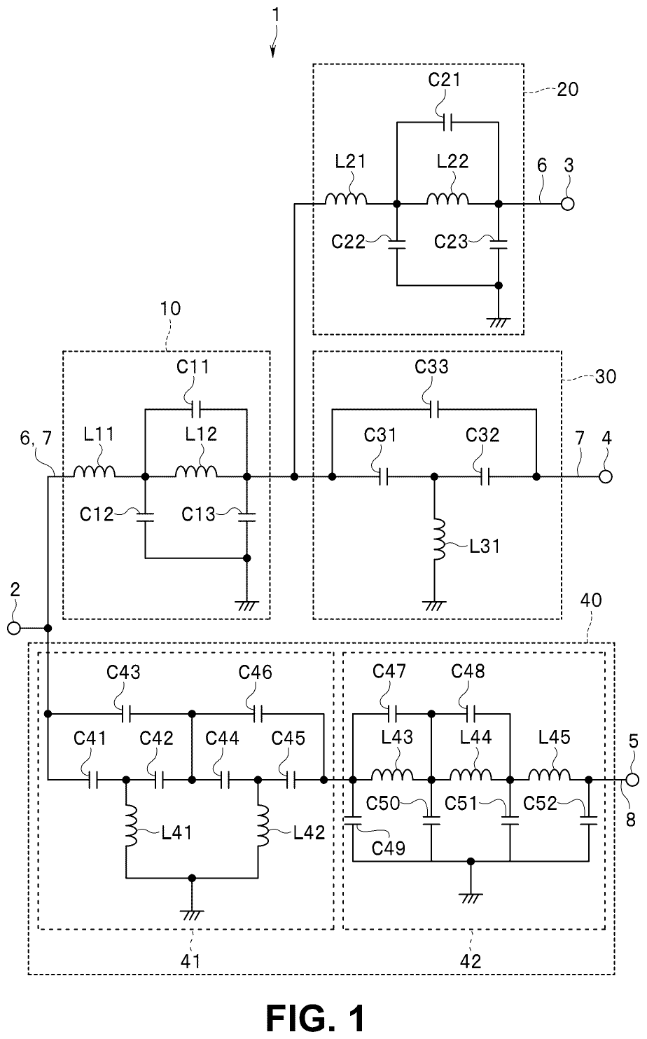

First, an overall configuration of a multilayered branching filter (hereinafter, simply referred to as a branching filter) 1 according to the exemplary embodiment of the disclosure is described with reference to FIG. 1. FIG. 1 is a circuit diagram showing a circuit configuration of the branching filter 1. The branching filter 1 includes a common terminal 2, a first signal terminal 3, a second signal terminal 4, a third signal terminal 5, a first path 6 that connects the common terminal 2 and the first signal terminal 3 to each other, a second path 7 that connects the common terminal 2 and the second signal terminal 4 to each other, and a third path 8 that connects the common terminal 2 and the third signal terminal 5 to each other.

The branching filter 1 is configured to function as a triplexer. The first path 6 is configured to selectively cause a signal having a frequency within a first passband to pass. The second path 7 is configured to selectively cause a signal having a frequency within a second passband to pass, the second passband being different from the first passband. The third path 8 is configured to selectively cause a signal having a frequency within a third passband to pass, the third passband being different from each of the first passband and the second passband. In the exemplary embodiment, in particular, the second passband is a frequency band higher than the first passband, and the third passband is a frequency band higher than the second passband.

The first path 6 and the second path 7 are a common path on the common terminal 2 side, and diverge from each other at an end of the common path on a side opposite to the common terminal 2. The branching filter 1 further includes filters 10, 20, and 30 and a filter unit 40. The filter 10 is provided to the common path described above. The filter 20 is provided to the first path 6 between the divergence point described above and the first signal terminal 3. The filter 30 is provided to the second path 7 between the divergence point described above and the second signal terminal 4. The filter unit 40 is provided to the third path 8.

The filter 10 is provided between the common terminal 2, and the first and second signal terminals 3 and 4 in the circuit configuration. The filter 20 is provided between the filter 10 and the first signal terminal 3 in the circuit configuration. The filter 30 is provided between the filter 10 and the second signal terminal 4 in the circuit configuration. The filter unit 40 is provided between the common terminal 2 and the third signal terminal 5 in the circuit configuration. Note that, in the present application, the expression “in the (a) circuit configuration” is used to indicate not a layout in a physical configuration but a layout in a circuit diagram.

The filter unit 40 includes a filter 41 and a filter 42. The filters 10, 20, and 42 may be low-pass filters. The filters 30 and 41 may be high-pass filters. In such a case, the first path 6 is provided with two low-pass filters (the filters 10 and 20). The second path 7 is provided with one low-pass filter (the filter 10) and one high-pass filter (the filter 30). The third path 8 is provided with one high-pass filter (the filter 41) and one low-pass filter (the filter 42). The one low-pass filter and the one high-pass filter that are provided to each of the second path 7 and the third path 8 form a band-pass filter.

A first signal that is input to the common terminal 2 and has a frequency within the first passband selectively passes through the filters 10 and 20, and is output from the first signal terminal 3. A second signal that is input to the common terminal 2 and has a frequency within the second passband selectively passes through the filters 10 and 30, and is output from the second signal terminal 4. A third signal that is input to the common terminal 2 and has a frequency within the third passband selectively passes through the filters 41 and 42, and is output from the third signal terminal 5. In this manner, the branching filter 1 separates the first to third signals from one another.

Next, an example of configurations of the filters 10, 20, 30, 41, and 42 is described with reference to FIG. 1. First, the filter 10 is described. The filter 10 includes inductors L11 and L12, and capacitors C11, C12, and C13. One end of the inductor L11 is connected to the common terminal 2. One end of the inductor L12 is connected to the other end of the inductor L11.

The capacitor C11 is connected in parallel to the inductor L12. One end of the capacitor C12 is connected to the connection point between the inductor L11 and the inductor L12. One end of the capacitor C13 is connected to the other end of the inductor L12. The other end of each of the capacitors C12 and C13 is connected to the ground.

Next, the filter 20 is described. The filter 20 includes inductors L21 and L22, and capacitors C21, C22, and C23. One end of the inductor L21 is connected to the other end of the inductor L12 of the filter 10. One end of the inductor L22 is connected to the other end of the inductor L21. The other end of the inductor L22 is connected to the first signal terminal 3.

The capacitor C21 is connected in parallel to the inductor L22. One end of the capacitor C22 is connected to the connection point between the inductor L21 and the inductor L22. One end of the capacitor C23 is connected to the other end of the inductor L22. The other end of each of the capacitors C22 and C23 is connected to the ground.

Next, the filter 30 is described. The filter 30 includes an inductor L31 and capacitors C31, C32, and C33. One end of the capacitor C31 is connected to the other end of the inductor L12 of the filter 10. One end of the capacitor C32 is connected to the other end of the capacitor C31. The other end of the capacitor C32 is connected to the second signal terminal 4. One end of the capacitor C33 is connected to one end of the capacitor C31. The other end of the capacitor C33 is connected to the other end of the capacitor C32.

One end of the inductor L31 is connected to the connection point between the capacitor C31 and the capacitor C32. The other end of the inductor L31 is connected to the ground.

Next, the filter 41 of the filter unit 40 is described. The filter 41 includes inductors L41 and L42, and capacitors C41, C42, C43, C44, C45, and C46. One end of the capacitor C41 is connected to the common terminal 2. One end of the capacitor C42 is connected to the other end of the capacitor C41. One end of the capacitor C43 is connected to one end of the capacitor C41. The other end of the capacitor C43 is connected to the other end of the capacitor C42.

One end of the capacitor C44 is connected to the other end of the capacitor C42. One end of the capacitor C45 is connected to the other end of the capacitor C44. One end of the capacitor C46 is connected to one end of the capacitor C44. The other end of the capacitor C46 is connected to the other end of the capacitor C45.

One end of the inductor L41 is connected to the connection point between the capacitor C41 and the capacitor C42. One end of the inductor L42 is connected to the connection point between the capacitor C44 and the capacitor C45. The other end of each of the inductors L41 and L42 is connected to the ground.

Next, the filter 42 of the filter unit 40 is described. The filter 42 includes inductors L43, L44, and L45, and capacitors C47, C48, C49, C50, C51, and C52. One end of the inductor L43 is connected to the other end of the capacitor C45 of the filter 41. One end of the inductor L44 is connected to the other end of the inductor L43. One end of the inductor L45 is connected to the other end of the inductor L44. The other end of the inductor L45 is connected to the third signal terminal 5.

The capacitor C47 is connected in parallel to the inductor L43. The capacitor C48 is connected in parallel to the inductor L44.

One end of the capacitor C49 is connected to one end of the inductor L43. One end of the capacitor C50 is connected to the connection point between the inductor L43 and the inductor L44. One end of the capacitor C51 is connected to the connection point between the inductor L44 and the inductor L45. One end of the capacitor C52 is connected to the other end of the inductor L45. The other end of each of the capacitors C49, C50, C51, and C52 is connected to the ground.

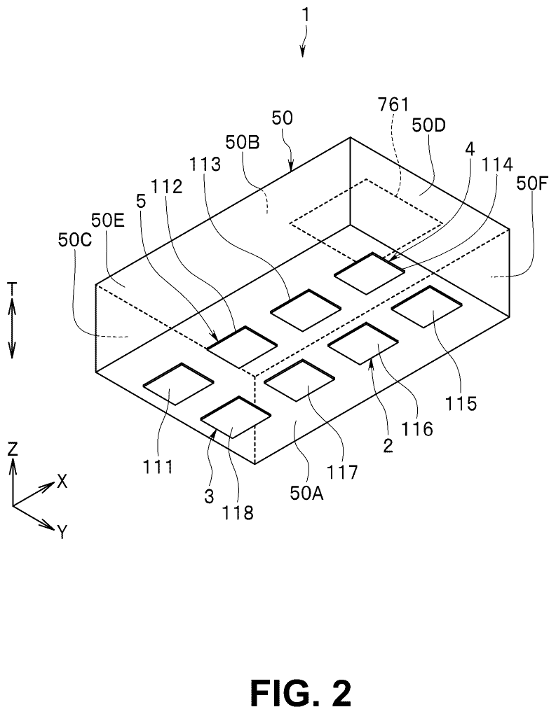

Next, with reference to FIG. 2, other configurations of the branching filter 1 are described. FIG. 2 is a perspective view showing an external appearance of the branching filter 1.

The branching filter 1 further includes a stack 50 including a plurality of dielectric layers being stacked and a plurality of conductors. The stack 50 is used for integrating the common terminal 2, the first to third signal terminals 3 to 5, the first to third paths 6 to 8, and the filters 10, 20, 30, 41, and 42. Each of the filters 10, 20, 30, 41, and 42 is configured by using the plurality of conductors.

The stack 50 includes a bottom surface 50A and a top surface 50B that are positioned on both ends in a stacking direction T of the plurality of dielectric layers and four side surfaces 50C to 50F that connect the bottom surface 50A and the top surface 50B. The side surfaces 50C and 50D are opposite to each other, and the side surfaces 50E and 50F are also opposite to each other. The side surfaces 50C to 50F are perpendicular to the bottom surface 50A and the top surface 50B.

Here, as shown in FIG. 2, an X direction, a Y direction, and a Z direction are defined. The X direction, the Y direction, and the Z direction are orthogonal to one another. In the exemplary embodiment, a direction parallel to the stacking direction T is referred to as the Z direction. A direction opposite to the X direction is referred to as a −X direction, a direction opposite to the Y direction is referred to as a −Y direction, and a direction opposite to the Z direction is referred to as a −Z direction. The expression “as seen in the (a) predetermined direction (for example, the stacking direction T)” indicates that a target object is seen from a position away from the target object in the predetermined direction or a direction parallel to the predetermined direction.

As shown in FIG. 2, the bottom surface 50A is positioned at the end of the stack 50 in the −Z direction. The top surface 50B is positioned at the end of the stack 50 in the Z direction. The side surface 50C is positioned at the end of the stack 50 in the −X direction. The side surface 50D is positioned at the end of the stack 50 in the X direction. The side surface 50E is positioned at the end of the stack 50 in the −Y direction. The side surface 50F is positioned at the end of the stack 50 in the Y direction.

The branching filter 1 further includes electrodes 111, 112, 113, 114, 115, 116, 117, and 118 that are provided to the bottom surface 50A of the stack 50. The electrodes 111, 112, 113, and 114 are arrayed in the stated order in the X direction at positions closer to the side surface 50E than the side surface 50F. The electrodes 115, 116, 117, and 118 are arrayed in the stated order in the −X direction at positions closer to the side surface 50F than the side surface 50E.

The electrode 116 corresponds to the common terminal 2, the electrode 118 corresponds to the first signal terminal 3, the electrode 114 corresponds to the second signal terminal 4, and the electrode 112 corresponds to the third signal terminal 5. Therefore, the common terminal 2, the first signal terminal 3, the second signal terminal 4, and the third signal terminal 5 are provided to the bottom surface 50A of the stack 50. Each of the electrodes 111, 113, 115, and 117 is connected to the ground.

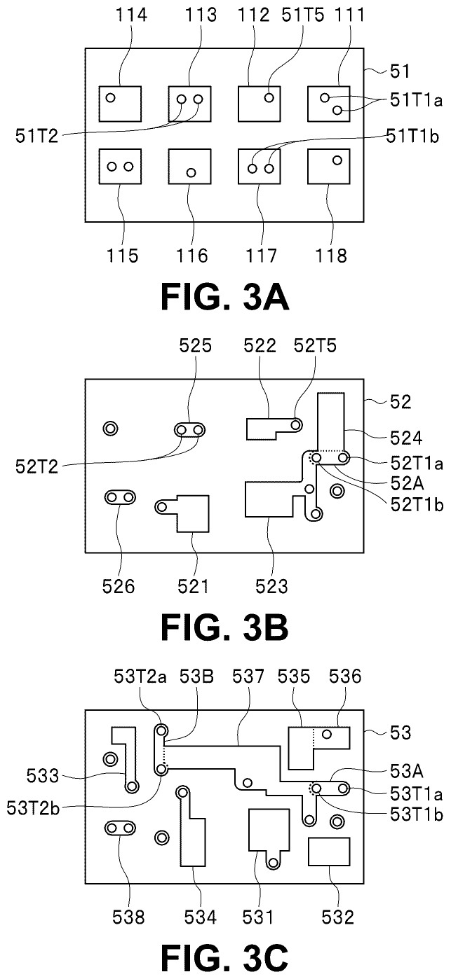

Next, with reference to FIG. 3A to FIG. 11B, an example of the plurality of dielectric layers and the plurality of conductors that form the stack 50 is described. In this example, the stack 50 includes 26 dielectric layers being stacked. The 26 dielectric layers are referred to as first to twenty-sixth dielectric layers in the order from bottom to top. The first to twenty-sixth dielectric layers are denoted by reference symbols 51 to 76, respectively.

In FIG. 3A to FIG. 10C, a plurality of circles indicate a plurality of through holes. In each of the dielectric layers 51 to 74, the plurality of through holes are formed. Each of the plurality of through holes is formed by filling a hole for a through hole with conductive paste. Each of the plurality of through holes is connected to an electrode, a conductor layer, or another through hole. In the following description, a connection relationship between each of the plurality of through holes and an electrode, a conductor layer, or another through hole is described with reference to a connection relationship in a state in which the first to twenty-sixth dielectric layers 51 to 76 are stacked. In FIG. 3A to FIG. 10C, a plurality of specific through holes among the plurality of through holes are denoted with reference symbols, respectively.

FIG. 3A shows the patterned surface of the first dielectric layer 51. On the patterned surface of the dielectric layer 51, the electrodes 111 to 118 are formed. Two through holes denoted with the reference symbol 51T1a in FIG. 3A are connected to the electrode 111. Note that, in the following description, the through hole denoted with the reference symbol 51T1a is simply described as a through hole 51T1a. Through holes denoted with reference symbols other than the through hole 51T1a are described similarly to the through hole 51T1a.

Two through holes 51T1b shown in FIG. 3A are connected to the electrode 117. Two through holes 51T2 shown in FIG. 3A are connected to the electrode 113. A through hole 51T5 shown in FIG. 3A is connected to the electrode 112.

FIG. 3B shows the patterned surface of the second dielectric layer 52. On the patterned surface of the dielectric layer 52, conductor layers 521, 522, 523, 524, 525, 526, and 52A are formed. The conductor layers 523 and 524 are connected to the conductor layer 52A. In FIG. 3B, the boundary between the conductor layer 523 and the conductor layer 52A and the boundary between the conductor layer 524 and the conductor layer 52A are indicated by the dot lines. Note that, in the drawings similar to FIG. 3B, which are used in the following description, the boundary between the two conductor layers is indicated by the dot line.

The two through holes 51T1a are connected to the conductor layer 524. The two through holes 51T1b are connected to the conductor layer 523. Through holes 52T1a and 52T1b shown in FIG. 3B are connected to the conductor layer 52A. The two through holes 51T2 and the two through holes 52T2 shown in FIG. 3B are connected to the conductor layer 525. The through hole 51T5 and a through hole 52T5 shown in FIG. 3B are connected to the conductor layer 522.

FIG. 3C shows the patterned surface of the third dielectric layer 53. On the patterned surface of the dielectric layer 53, conductor layers 531, 532, 533, 534, 535, 536, 537, 538, 53A, and 53B are formed. The conductor layer 536 is connected to the conductor layer 535. The conductor layers 53A and 53B are connected to the conductor layer 537.

The two through holes 52T2 are connected to the conductor layer 537. The through hole 52T5 is connected to the conductor layer 535. The through holes 52T1a and 52T1b and through holes 53T1a and 53T1b shown in FIG. 3C are connected to the conductor layer 53A. Through holes 53T2a and 53T2b shown in FIG. 3C are connected to the conductor layer 53B.

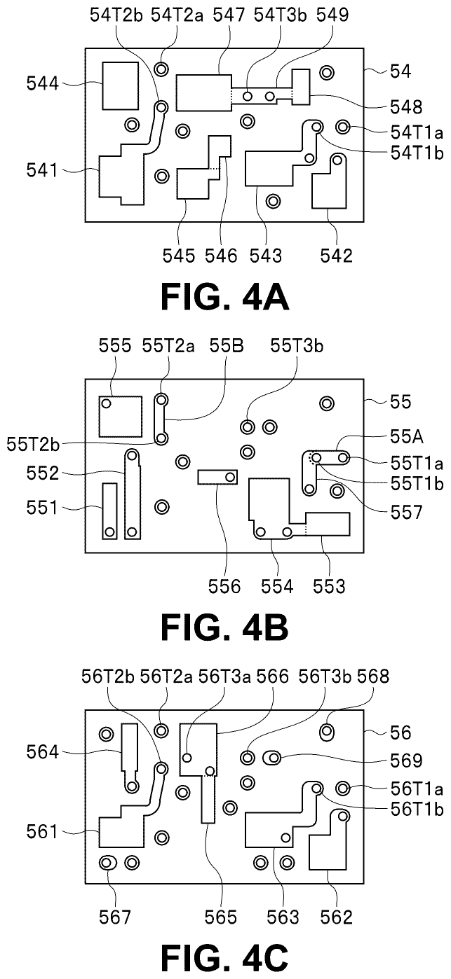

FIG. 4A shows the patterned surface of the fourth dielectric layer 54. On the patterned surface of the dielectric layer 54, conductor layers 541, 542, 543, 544, 545, 546, 547, 548, and 549 are formed. The conductor layer 546 is connected to the conductor layer 545. The conductor layers 547 and 548 are connected to the conductor layer 549.

The through holes 53T1a and 53T2a are connected to through holes 54T1a and 54T2a shown in FIG. 4A, respectively. The through hole 53T1b and the through hole 54T1b shown in FIG. 4A are connected to the conductor layer 543. The through hole 53T2b and a through hole 54T2b shown in FIG. 4A are connected to the conductor layer 541. A through hole 54T3b shown in FIG. 4A is connected to the conductor layer 549.

FIG. 4B shows the patterned surface of the fifth dielectric layer 55. On the patterned surface of the dielectric layer 55, conductor layers 551, 552, 553, 554, 555, 556, 557, 55A, and 55B are formed. The conductor layer 554 is connected to the conductor layer 553. The conductor layer 557 is connected to the conductor layer 55A.

The through holes 54T1a and 54T1b and through holes 55T1a and 55T1b shown in FIG. 4B are connected to the conductor layer 55A. The through holes 54T2a and 54T2b and through holes 55T2a and 55T2b shown in FIG. 4B are connected to the conductor layer 55B. The through hole 54T3b is connected to a through hole 55T3b shown in FIG. 4B.

FIG. 4C shows the patterned surface of the sixth dielectric layer 56. On the patterned surface of the dielectric layer 56, conductor layers 561, 562, 563, 564, 565, 566, 567, 568, and 569 are formed. The conductor layer 566 is connected to the conductor layer 565.

The through holes 55T1a, 55T2a, and 55T3b are connected to through holes 56T1a, 56T2a, and 56T3b shown in FIG. 4C, respectively. The through hole 55T1b and a through hole 56T1b shown in FIG. 4C are connected to the conductor layer 563. The through hole 55T2b and a through hole 56T2b shown in FIG. 4C are connected to the conductor layer 561. A through hole 56T3a shown in FIG. 4C is connected to the conductor layer 566.

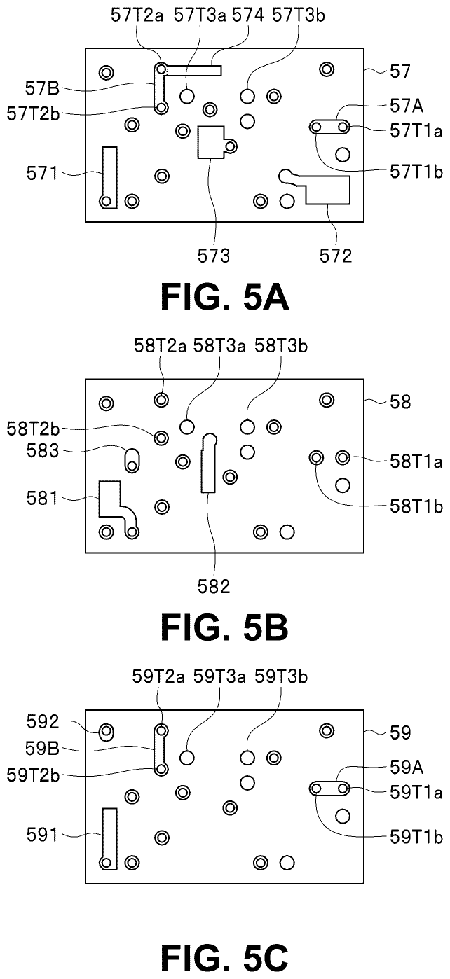

FIG. 5A shows the patterned surface of the seventh dielectric layer 57. On the patterned surface of the dielectric layer 57, conductor layers 571, 572, 573, 574, 57A, and 57B are formed. The conductor layer 574 is connected to the conductor layer 57B.

The through holes 56T1a and 56T1b and through holes 57T1a and 57T1b shown in FIG. 5A are connected to the conductor layer 57A. The through holes 56T2a and 56T2b and through holes 57T2a and 57T2b shown in FIG. 5A are connected to the conductor layer 57B. The through holes 56T3a and 56T3b are connected to through holes 57T3a and 57T3b shown in FIG. 5A, respectively.

FIG. 5B shows the patterned surface of the eighth dielectric layer 58. On the patterned surface of the dielectric layer 58, conductor layers 581, 582, and 583 are formed. The through holes 57T1a, 57T1b, 57T2a, 57T2b, 57T3a, and 57T3b are to through holes 58T1a, 58T1b, 58T2a, 58T2b, 58T3a, and 58T3b shown in FIG. 5B, respectively.

FIG. 5C shows the patterned surface of the ninth dielectric layer 59. On the patterned surface of the dielectric layer 59, conductor layers 591, 592, 59A, and 59B are formed. The through holes 58T1a and 58T1b and through holes 59T1a and 59T1b shown in FIG. 5C are connected to the conductor layer 59A. The through holes 58T2a and 58T2b and through holes 59T2a and 59T2b shown in FIG. 5C are connected to the conductor layer 59B. The through holes 58T3a and 58T3b are connected to through holes 59T3a and 59T3b shown in FIG. 5C, respectively.

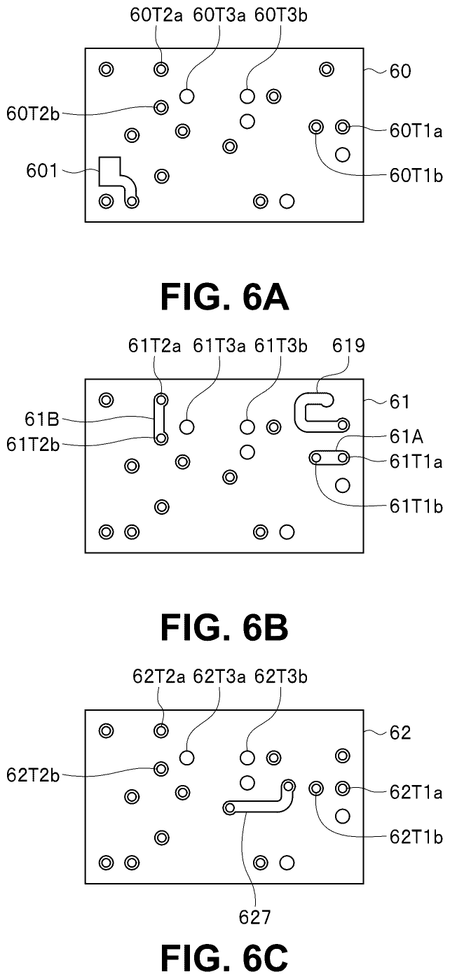

FIG. 6A shows the patterned surface of the tenth dielectric layer 60. On the patterned surface of the dielectric layer 60, a conductor layer 601 is formed. The through holes 59T1a, 59T1b, 59T2a, 59T2b, 59T3a, and 59T3b are connected to through holes 60T1a, 60T1b, 60T2a, 60T2b, 60T3a, and 60T3b shown in FIG. 6A, respectively.

FIG. 6B shows the patterned surface of the eleventh dielectric layer 61. On the patterned surface of the dielectric layer 61, an inductor conductor layer 619 and conductor layers 61A and 61B are formed. The through holes 60T1a and 60T1b and through holes 61T1a and 61T1b shown in FIG. 6B are connected to the conductor layer 61A. The through holes 60T2a and 60T2b and through holes 61T2a and 61T2b shown in FIG. 6B are connected to the conductor layer 61B. The through holes 60T3a and 60T3b are connected to through holes 61T3a and 61T3b shown in FIG. 6B.

FIG. 6C shows the patterned surface of the twelfth dielectric layer 62. On the patterned surface of the dielectric layer 62, a conductor layer 627 is formed. The through holes 61T1a, 61T1b, 61T2a, 61T2b, 61T3a, and 61T3b are connected to through holes 62T1a, 62T1b, 62T2a, 62T2b, 62T3a, and 62T3b shown in FIG. 6C, respectively.

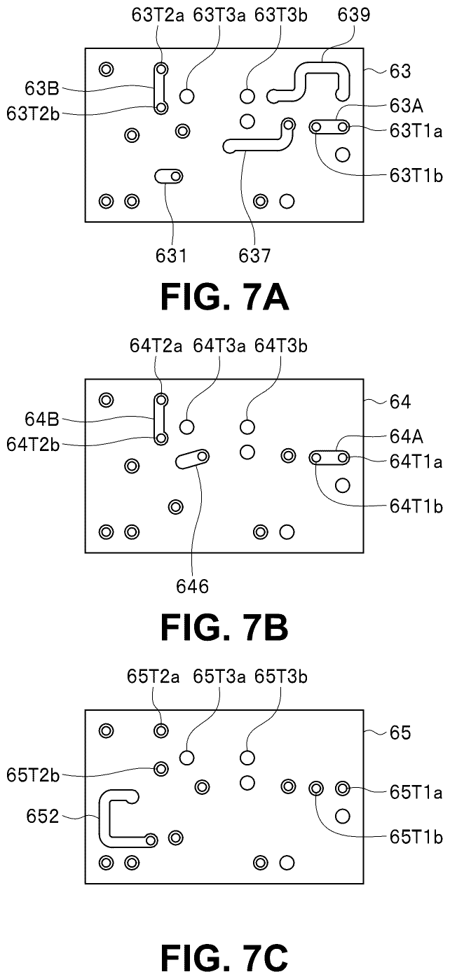

FIG. 7A shows the patterned surface of the thirteenth dielectric layer 63. On the patterned surface of the dielectric layer 63, conductor layers 631, 637, 63A, and 63B, and an inductor conductor layer 639 are formed. The through holes 62T1a and 62T1b and through holes 63T1a and 63T1b shown in FIG. 7A are connected to the conductor layer 63A. The through holes 62T2a and 62T2b and through holes 63T2a and 63T2b shown in FIG. 7A are connected to the conductor layer 63B. The through holes 62T3a and 62T3b are connected to through holes 63T3a and 63T3b shown in FIG. 7A, respectively.

FIG. 7B shows the patterned surface of the fourteenth dielectric layer 64. On the patterned surface of the dielectric layer 64, conductor layers 646, 64A, and 64B are formed. The through holes 63T1a and 63T1b and through holes 64T1a and 64T1b shown in FIG. 7B are connected to the conductor layer 64A. The through holes 63T2a and 63T2b and through holes 64T2a and 64T2b shown in FIG. 7B are connected to the conductor layer 64B. The through holes 63T3a and 63T3b are connected to through holes 64T3a and 64T3b shown in FIG. 7B, respectively.

FIG. 7C shows the patterned surface of the fifteenth dielectric layer 65. On the patterned surface of the dielectric layer 65, an inductor conductor layer 652 is formed. The through holes 64T1a, 64T1b, 64T2a, 64T2b, 64T3a, and 64T3b are connected to through holes 65T1a, 65T1b, 65T2a, 65T2b, 65T3a, and 65T3b shown in FIG. 7C, respectively.

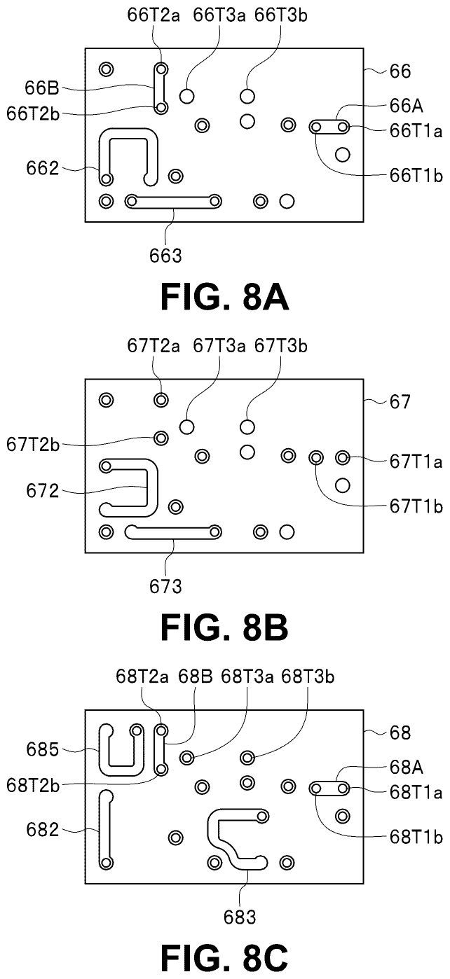

FIG. 8A shows the patterned surface of the sixteenth dielectric layer 66. On the patterned surface of the dielectric layer 66, an inductor conductor layer 662 and conductor layers 663, 66A, and 66B are formed. The through holes 65T1a and 65T1b and through holes 66T1a and 66T1b shown in FIG. 8A are connected to the conductor layer 66A. The through holes 65T2a and 65T2b and through holes 66T2a and 66T2b shown in FIG. 8A are connected to the conductor layer 66B. The through holes 65T3a and 65T3b are connected to through holes 66T3a and 66T3b shown in FIG. 8A, respectively.

FIG. 8B shows the patterned surface of the seventeenth dielectric layer 67. On the patterned surface of the dielectric layer 67, an inductor conductor layer 672 and a conductor layer 673 are formed. The through holes 66T1a, 66T1b, 66T2a, 66T2b, 66T3a, and 66T3b are connected to through holes 67T1a, 67T1b, 67T2a, 67T2b, 67T3a, and 67T3b shown in FIG. 8B, respectively.

FIG. 8C shows the patterned surface of the eighteenth dielectric layer 68. On the patterned surface of the dielectric layer 68, inductor conductor layers 682, 683, and 685, and conductor layers 68A and 68B are formed. The through holes 67T1a and 67T1b and through holes 68T1a and 68T1b shown in FIG. 8C are connected to the conductor layer 68A. The through holes 67T2a and 67T2b and through holes 68T2a and 68T2b shown in FIG. 8C are connected to the conductor layer 68B. The through holes 67T3a and 67T3b are connected to through holes 68T3a and 68T3b shown in FIG. 8C, respectively.

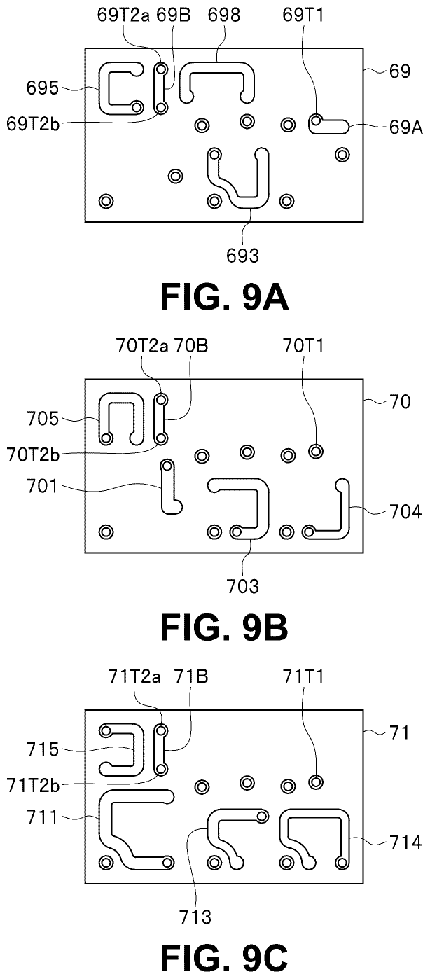

FIG. 9A shows the patterned surface of the nineteenth dielectric layer 69. On the patterned surface of the dielectric layer 69, inductor conductor layers 693, 695, and 698, and conductor layers 69A and 69B are formed. The conductor layer 698 includes a first end and a second end that are positioned on opposite sides in a longitudinal direction of the conductor layer 698. The through hole 68T3a is connected to a part in the vicinity of the first end of the conductor layer 698. The through hole 68T3b is connected to a part in the vicinity of the second end of the conductor layer 698.

The through holes 68T1a and 68T1b and a through hole 69T1 shown in FIG. 9A are connected to the conductor layer 69A. The through holes 68T2a and 68T2b and through holes 69T2a and 69T2b shown in FIG. 9A are connected to the conductor layer 69B.

FIG. 9B shows the patterned surface of the twentieth dielectric layer 70. On the patterned surface of the dielectric layer 70, inductor conductor layers 701, 703, 704, and 705, and a conductor layer 70B are formed. The through holes 69T2a and 69T2b and through holes 70T2a and 70T2b shown in FIG. 9B are connected to the conductor layer 70B. The through hole 69T1 is connected to the through hole 70T1 shown in FIG. 9B.

FIG. 9C shows the patterned surface of the twenty-first dielectric layer 71. On the patterned surface of the dielectric layer 71, inductor conductor layers 711, 713, 714, and 715, and a conductor layer 71B are formed. The through holes 70T2a and 70T2b and through holes 71T2a and 71T2b shown in FIG. 9C are connected to the conductor layer 71B. The through hole 70T1 is connected to the through hole 71T1 shown in FIG. 9C.

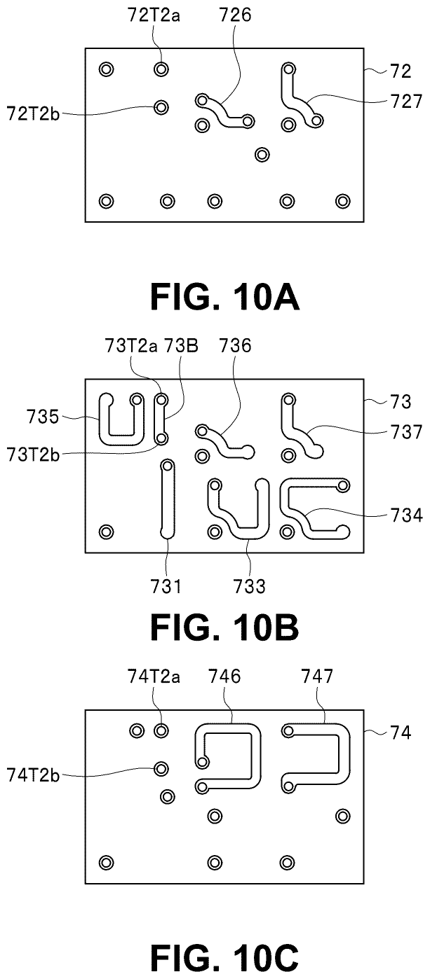

FIG. 10A shows the patterned surface of the twenty-second dielectric layer 72. On the patterned surface of the dielectric layer 72, inductor conductor layers 726 and 727 are formed. The through holes 71T2a and 71T2b are connected to through holes 72T2a and 72T2b shown in FIG. 10A, respectively. The through hole 71T1 is connected to the conductor layer 727.

FIG. 10B shows the patterned surface of the twenty-third dielectric layer 73. On the patterned surface of the dielectric layer 73, inductor conductor layers 731, 733, 734, 735, 736, and 737, and a conductor layer 73B are formed. The through holes 72T2a and 72T2b and through holes 73T2a and 73T2b shown in FIG. 10B are connected to the conductor layer 73B.

FIG. 10C shows the patterned surface of the twenty-fourth dielectric layer 74. On the patterned surface of the dielectric layer 74, inductor conductor layers 746 and 747 are formed. The through holes 73T2a and 73T2b are connected to through holes 74T2a and 74T2b shown in FIG. 10C, respectively.

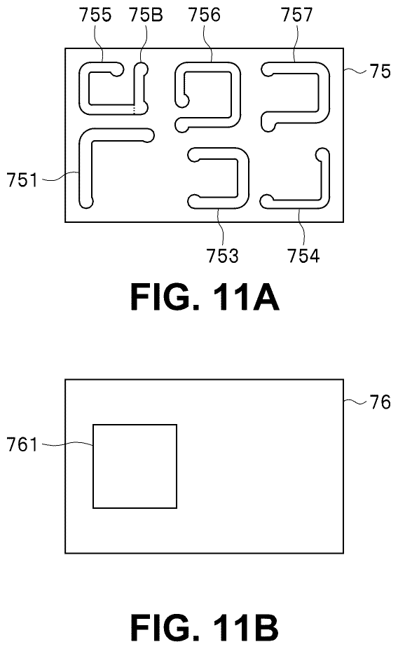

FIG. 11A shows the patterned surface of the twenty-fifth dielectric layer 75. On the patterned surface of the dielectric layer 75, inductor conductor layers 751, 753, 754, 755, 756, and 757, and a conductor layer 75B are formed. The conductor layer 755 is connected to the conductor layer 75B. The through holes 74T2a and 74T2b are connected to the conductor layer 75B.

FIG. 11B shows the patterned surface of the twenty-sixth dielectric layer 76. On the patterned surface of the dielectric layer 76, a mark 761 is formed.

The stack 50 shown in FIG. 2 is formed by stacking the first to twenty-sixth dielectric layers 51 to 76 so that the patterned surface of the first dielectric layer 51 serves as the bottom surface 50A of the stack 50 and the surface opposite to the patterned surface of the twenty-sixth dielectric layer 76 serves as the top surface 50B of the stack 50.

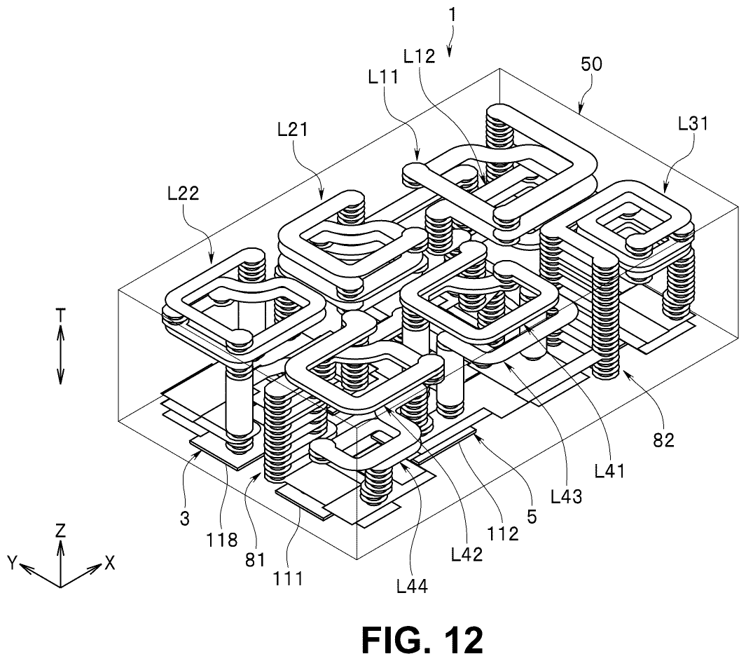

FIG. 12 shows the internal structure of the stack 50 formed by stacking the first to twenty-sixth dielectric layers 51 to 76. As shown in FIG. 12, the plurality of conductor layers and the plurality of through holes, which are shown in FIG. 3A to FIG. 11B, are stacked inside the stack 50. Note that, in FIG. 12, the mark 761 is omitted.

Correspondence between the constituent elements of the branching filter 1 shown in FIG. 1 and the constituent elements inside the stack 50, which are shown in FIG. 3A to FIG. 11B, is described below. First, the constituent elements of the filter 10 are described. The inductor L11 is formed of the inductor conductor layers 701, 711, 731, and 751 and the plurality of through holes that connect those conductor layers to each other. The inductor L12 is formed of the inductor conductor layers 652, 662, 672, and 682 and the plurality of through holes that connect those conductor layers to each other.

The capacitor C11 is formed of the conductor layers 571, 581, 591, and 601 and the dielectric layers 57 to 59 between those conductor layers. The capacitor C12 is formed of the conductor layers 541, 551, 561, and 571 and the dielectric layers 54 to 56 between those conductor layers. The capacitor C13 is formed of the conductor layers 541, 552, and 561 and the dielectric layers 54 and 55 between those conductor layers.

Next, the constituent elements of the filter 20 are described. The inductor L21 is formed of the inductor conductor layers 683, 693, 703, 713, 733, and 753 and the plurality of through holes that connect those conductor layers to each other. The inductor L22 is formed of the inductor conductor layers 704, 714, 734, and 754 and the plurality of through holes that connect those conductor layers to each other.

The capacitor C21 is formed of the conductor layers 553 and 562 and the dielectric layer 55 between those conductor layers. The capacitor C22 is formed of the conductor layers 523, 531, 543, 554, and 563 and the dielectric layers 54 and 55 between those conductor layers. The capacitor C23 is formed of the conductor layers 532, 542, 562, and 572 and the dielectric layers 53 and 56 between those conductor layers.

Next, the constituent elements of the filter 30 are described. The inductor L31 is formed of the inductor conductor layers 685, 695, 705, 715, 735, and 755 and the plurality of through holes that connect those conductor layers to each other.

The capacitor C31 is formed of the conductor layers 555 and 564 and the dielectric layer 55 between those conductor layers. The capacitor C32 is formed of the conductor layers 544 and 555 and the dielectric layer 54 between those conductor layers. The capacitor C33 is formed of the conductor layers 533 and 544 and the dielectric layer 53 between those conductor layers.

Next, the constituent elements of the filter 41 of the filter unit 40 are described. The inductor L41 is formed of the inductor conductor layers 726, 736, 746, and 756 and the plurality of through holes that connect those conductor layers to each other. The inductor L42 is formed of the inductor conductor layers 727, 737, 747, and 757 and the plurality of through holes that connect those conductor layers to each other.

The capacitor C41 is formed of the conductor layers 521 and 534 and the dielectric layer 52 between those conductor layers. The capacitor C42 is formed of the conductor layers 534 and 545 and the dielectric layer 53 between those conductor layers. The capacitor C43 is formed of the conductor layers 521 and 545 and the dielectric layers 52 and 53 between those conductor layers.

The capacitor C44 is formed of the conductor layers 546 and 556 and the dielectric layer 54 between those conductor layers. The capacitor C45 is formed of the conductor layers 556 and 565 and the dielectric layer 55 between those conductor layers. The capacitor C46 is formed of the conductor layers 546 and 565 and the dielectric layers 54 and 55 between those conductor layers.

Next, the constituent elements of the filter 42 of the filter unit 40 are described. The inductor L43 is formed of the inductor conductor layers 698 and the through holes 54T3b, 55T3b, 56T3a, 56T3b, 57T3a, 57T3b, 58T3a, 58T3b, 59T3a, 59T3b, 60T3a, 60T3b, 61T3a, 61T3b, 62T3a, 62T3b, 63T3a, 63T3b, 64T3a, 64T3b, 65T3a, 65T3b, 66T3a, 66T3b, 67T3a, 67T3b, 68T3a, and 68T3b. The inductor L44 is formed of the inductor conductor layers 619 and 639 and the plurality of through holes that connect those conductor layers to each other. The inductor L45 is formed of the through hole 52T5.

The capacitor C47 is formed of the conductor layers 547 and 566 and the dielectric layers 54 and 55 between those conductor layers. The capacitor C48 is formed of the conductor layers 535 and 548 and the dielectric layer 53 between those conductor layers. The capacitor C49 is formed of the conductor layers 566 and 574 and the dielectric layer 56 between those conductor layers. The capacitor C50 is formed of the conductor layers 537 and 547 and the dielectric layer 53 between those conductor layers. The capacitor C51 is formed of the conductor layers 524 and 536 and the dielectric layer 52 between those conductor layers. The capacitor C52 is formed of the conductor layers 522 and 537 and the dielectric layer 52 between those conductor layers.

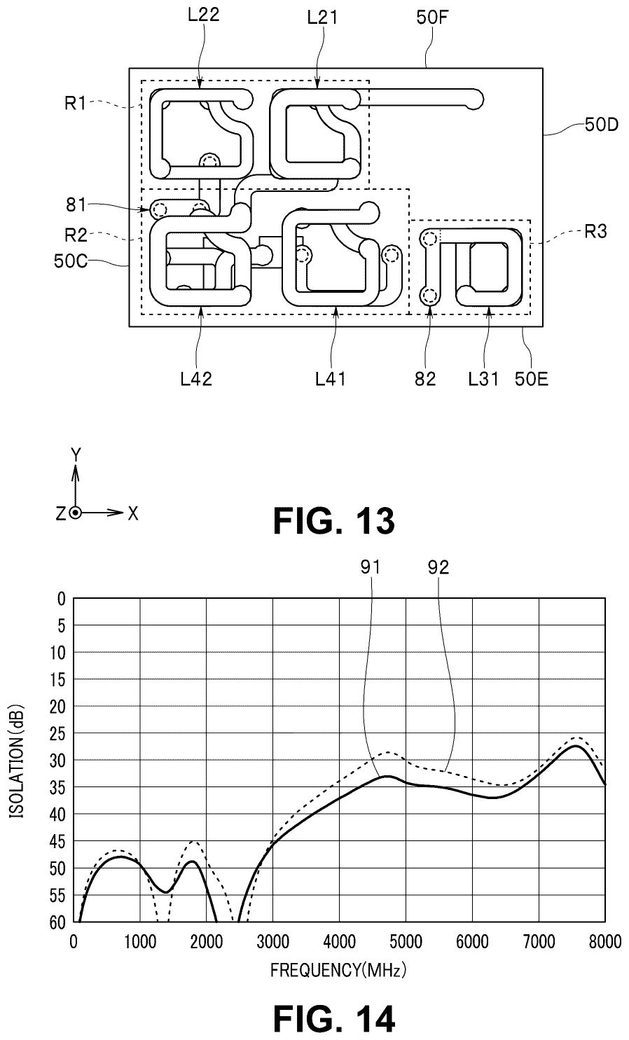

Next, with reference to FIG. 3A to FIG. 13, the structural features of the branching filter 1 according to the exemplary embodiment are described. FIG. 13 is a plan view showing a part of the internal structure of the stack 50. The stack 50 includes a first region R1 and a second region R2 that are adjacent to each other, and a third region R3 adjacent to the second region R2. Each of the first to third regions R1 to R3 is defined as a three-dimensional region for arranging a plurality of elements inside the stack 50.

The first region R1 is a region mainly for arranging a plurality of elements forming the filter 20. The second region R2 is a region mainly for arranging a plurality of elements forming the filters 41 and 42 of the filter unit 40. The third region R3 is a region mainly for arranging a plurality of elements forming the filter 30. The filter 20 is substantially arranged in the first region R1. The filters 41 and 42 are substantially arranged in the second region R2. The filter 30 is substantially arranged in the third region R3.

The first region R1 includes the entire the inductors L21 and L22. The second region R2 includes the entire inductors L41 to L45. The third region includes the entire inductor L31.

Note that a plurality of elements forming the filter 10 are arranged in a region within the stack 50 other than the first to third regions R1 to R3. The filter 10 is substantially arranged in a region within the stack 50 other than the first to third regions R1 to R3.

The stack 50 further includes a structure body 81 that are arranged in the vicinity of the boundary between the first region R1 and the second region R2 and a structure body 82 that are arranged in the vicinity of the boundary between the second region R2 and the third region R3. In the exemplary embodiment, in particular, the structure body 81 is arranged in the second region R2. The structure body 82 is arranged in the third region R3. Each of the structure bodies 81 and 82 is connected to the ground.

The structure body 81 includes a plurality of first sub structure bodies that are stacked in a direction parallel to the stacking direction T. Each of the plurality of first sub structure bodies includes a plurality of first through holes and a first conductor layer that connects the plurality of first through holes. In the exemplary embodiment, the structure body 81 includes the through holes 52T1a, 52T1b, 53T1a, 53T1b, 54T1a, 54T1b, 55T1a, 55T1b, 56T1a, 56T1b, 57T1a, 57T1b, 58T1a, 58T1b, 59T1a, 59T1b, 60T1a, 60T1b, 61T1a, 61T1b, 62T1a, 62T1b, 63T1a, 63T1b, 64T1a, 64T1b, 65T1a, 65T1b, 66T1a, 66T1b, 67T1a, 67T1b, 68T1a, and 68T1b as a plurality of first through holes forming the plurality of first sub structure bodies. The structure body 81 includes the conductor layers 52A, 53A, 55A, 57A, 59A, 61A, 63A, 64A, 66A, 68A, and 69A as a plurality of first conductor layers forming the plurality of first sub structure bodies.

The conductor layer 52A connects the through holes 52T1a and 52T1b that are at the same position in the stacking direction T. The through holes 52T1a and 52T1b and the conductor layer 52A form one first sub structure body. Similarly, two through holes of the plurality of first through holes, which are at the same position in the stacking direction T, and the conductor layer connecting those two through holes form one first sub structure body. The structure body 81 is formed by stacking the plurality of first sub structure bodies thus formed.

Among the plurality of first sub structure bodies, two first sub structure bodies adjacent to each other in the stacking direction T may be connected directly to each other, or may be connected to each other via the through hole. Herein, description is made while focusing on the first sub structure bodies including the conductor layer 55A. The first sub structure bodies including the conductor layer 55A include the first sub structure body including the through holes 54T1a and 54T1b and the conductor layer 55A and the first sub structure body including the through holes 55T1a and 55T1b and the conductor layer 55A. It can be said that the first sub structure body including the through holes 54T1a and 54T1b and the conductor layer 55A is connected directly to the first sub structure body including the through holes 53T1a, 53T1b and the conductor layer 53A. It can be said that the first sub structure body including the through holes 55T1a and 55T1b and the conductor layer 55A is connected directly to the first sub structure body including the through holes 53T1a, 53T1b and the conductor layer 53A via the through holes 54T1a and 54T1b.

The structure body 81 is connected to the ground via the electrode 111, the two through holes 51T1a, and the conductor layer 524, and is connected to the ground via the electrode 117, the two through holes 51T1b, and the conductor layer 523.

The structure body 81 includes a first end and a second end that are positioned on opposite sides in the stacking direction T. In the exemplary embodiment, the conductor layer 52A substantially serves as the first end of the structure body 81, and the conductor layer 69A substantially serves as the second end of the structure body 81.

The structure body 82 includes a plurality of second sub structure bodies that are stacked in a direction parallel to the stacking direction T. Each of the plurality of second sub structure bodies includes a plurality of second through holes and a second conductor layer that connects the plurality of second through holes. In the exemplary embodiment, the structure body 82 includes the through holes 53T2a, 53T2b, 54T2a, 54T2b, 55T2a, 55T2b, 56T2a, 56T2b, 57T2a, 57T2b, 58T2a, 58T2b, 59T2a, 59T2b, 60T2a, 60T2b, 61T2a, 61T2b, 62T2a, 62T2b, 63T2a, 63T2b, 64T2a, 64T2b, 65T2a, 65T2b, 66T2a, 66T2b, 67T2a, 67T2b, 68T2a, 68T2b, 69T2a, 69T2b, 70T2a, 70T2b, 71T2a, 71T2b, 72T2a, 72T2b, 73T2a, 73T2b, 74T2a, and 74T2b as a plurality of second through holes forming the plurality of second sub structure bodies. The structure body 82 includes the conductor layers 53B, 55B, 57B, 59B, 61B, 63B, 64B, 66B, 68B, 69B, 70B, 71B, 73B, and 75B as a plurality of second conductor layers forming the plurality of second sub structure bodies.

The conductor layer 53B connects the through holes 53T2a and 53T2b that are same position in the stacking direction T. The through holes 53T2a and 53T2b and the conductor layer 53B form one second sub structure body. Similarly, two through holes of the plurality of second through holes, which are at the same position in the stacking direction T, and the conductor layer connecting those two through holes form one second sub structure body. The structure body 82 is formed by stacking the plurality of second sub structure bodies thus formed.

Similarly to the plurality of first sub structure bodies, among the plurality of second sub structure bodies, two second sub structure bodies adjacent to each other in the stacking direction T may be connected directly to each other, or may be connected to each other via the through hole.

The structure body 82 is connected to the ground via the electrode 113, the two through holes 51T2, the conductor layer 525, the two through holes 52T2, and the conductor layer 537.

The structure body 82 includes a first end and a second end that are positioned on opposite sides in the stacking direction T. In the exemplary embodiment, the conductor layer 53B substantially serves as the first end of the structure body 82, and the conductor layer 75B substantially serves as the second end of the structure body 82.

Next, a relationship between the structure body 81 and the plurality of elements provided inside the stack 50 is described. The inductor L42 of the filter 41 of the filter unit 40 is arranged in the second region R2. The inductor conductor layer 727 that forms the inductor L42 is connected to the conductor layer 69A that forms the structure body 81, via the through holes 69T1, 70T1, and 71T1. The conductor layer 69A is positioned at the end of the structure body 81 in the Z direction. The conductor layer 727 and the conductor layer 69A are arranged at positions different from each other in the stacking direction T. A part of the inductor L42 overlaps with the structure body 81 as viewed in the stacking direction T.

In a region in the vicinity of the structure body 81 in the first region R1, the inductor L22 of the filter 20 is arranged. The inductor L22 and the inductor L42 are arranged so that at least a part of the structure body 81 is interposed between the inductor L22 and the inductor L42 as viewed in the stacking direction T. In the exemplary embodiment, in particular, a part of the structure body 81 is interposed between the inductor L22 and the inductor L42.

The conductor layer for forming an element different from the inductor L42 is also connected to the structure body 81. In the exemplary embodiment, the conductor layers 523, 543, and 563 for forming the capacitor C22 of the filter 20 and the conductor layer 524 for forming the capacitor C51 of the filter 42 of the filter unit 40 are connected to the structure body 81. Each of the conductor layers 523, 543, and 563 extends from the structure body 81 to the first region R1. The conductor layers 543 and 563 are connected to the structure body 81 between the first end of the structure body 81 (the conductor layer 52A) and the second end of the structure body 81 (the conductor layer 69A).

Next, a relationship between the structure body 82 and the plurality of elements provided inside the stack 50 is described. The inductor L31 of the filter 30 is arranged in the third region R3. The inductor conductor layer 755 that forms the inductor L31 is connected to the conductor layer 75B that forms the structure body 82. The conductor layer 75B is positioned at the end of the structure body 82 in the Z direction. The conductor layer 755 and the conductor layer 75B are arranged at the same position in the stacking direction T. In the exemplary embodiment, in particular, the conductor layer 755 is also positioned at the end of the inductor L31 in the Z direction.

In a region in the vicinity of the structure body 82 in the second region R2, the inductor L41 of the filter 41 of the filter unit 40 is arranged. The inductor L31 and the inductor L41 are arranged so that at least a part of the structure body 82 is interposed between the inductor L31 and the inductor L41 as viewed in the stacking direction T. In the exemplary embodiment, in particular, the entire structure body 82 is interposed between the inductor L31 and the inductor L41.

A conductor layer for forming an element different from the inductor L31 is also connected to the structure body 82. In the exemplary embodiment, the conductor layers 541 and 561 for forming the capacitors C12 and C13 of the filter 10, the conductor layer 574 for forming the capacitor C49 of the filter 42 of the filter unit 40, and the conductor layer 537 for forming the capacitors C50 and C52 of the filter 42 of the filter unit 40 are connected to the structure body 82. The conductor layer 574 extends from the structure body 82 to the second region R2. The conductor layers 541, 561, and 574 are connected to the structure body 82 between the first end of the structure body 82 (the conductor layer 53B) and the second end of the structure body 82 (the conductor layer 75B).

Next, actions and effects of the branching filter 1 according to the exemplary embodiment are described. In the exemplary embodiment, the structure body 81 is arranged in the vicinity of the boundary between the first region R1 and the second region R2. The inductor L42 arranged in the second region R2 is connected to the structure body 81. With this, according to the exemplary embodiment, the inductor L42 is coupled to the elements arranged in the first region R1, and thus degradation of isolation between the first region R1 and the second region R2 can be prevented. As a result, according to the exemplary embodiment, isolation between the first region R1 and the second region R2 can be secured.

In the exemplary embodiment, in particular, the first region R1 is a region mainly for arranging the plurality of elements forming the filter 20. The second region R2 is a region mainly for arranging the plurality of elements forming the filters 41 and 42 of the filter unit 40. In a region in the vicinity of the structure body 81 in the first region R1, the inductor L22 of the filter 20 is arranged. In a region in the vicinity of the inductor L22 in the second region R2, the inductor L42 of the filter 41 of the filter unit 40 is arranged. Therefore, according to the exemplary embodiment, the structure body 81 can secure isolation between the filter 20 and the filter 41.

Similarly, in the exemplary embodiment, the structure body 82 is arranged in the vicinity of the boundary between the second region R2 and the third region R3. The inductor L31 arranged in the third region R3 is connected to the structure body 82. With this, according to the exemplary embodiment, the inductor L31 is coupled to the elements arranged in the second region R2, and thus degradation of isolation between the second region R2 and the third region R3 can be prevented. As a result, according to the exemplary embodiment, isolation between the second region R2 and the third region R3 can be secured.

In the exemplary embodiment, in particular, the third region R3 is a region mainly for arranging the plurality of elements forming the filter 30. In a region in the vicinity of the structure body 82 in the second region R2, the inductor L41 of the filter 41 of the filter unit 40 is arranged. In a region in the vicinity of the inductor L41 in the third region R3, the inductor L31 of the filter 30 is arranged. Therefore, according to the exemplary embodiment, the structure body 82 can secure isolation between the filter 30 and the filter 41.

With reference to the simulation results, the effects described above are described below in detail. In the simulation, a model in an example and a model in a comparative example are used. The model in the example is a model of the branching filter 1 according to the exemplary embodiment. The model in the comparative example is a model of a branching filter in the comparative example. The branching filter in the comparative example includes a first columnar conductor in place of the structure body 81 of the exemplary embodiment, and includes a second columnar conductor in place of the structure body 82 of the exemplary embodiment. Each of the first and second columnar conductors is configured by connecting the plurality of through holes in series, and extends in a direction parallel to the stacking direction T.

In the simulation, for each of the model in the example and the model in the comparative example, frequency characteristics of isolation between the first signal terminal 3 and the third signal terminal 5 and frequency characteristics of isolation between the second signal terminal 4 and the third signal terminal 5 are obtained.

Isolation between the two terminals is defined as follows. When a high-frequency signal with power P1 is input to one of the two terminals, power of a signal that is output from the other of the two terminals is P2. Isolation I is defined in Expression (1) given below.

I=−10 log(P2/P1) (1)

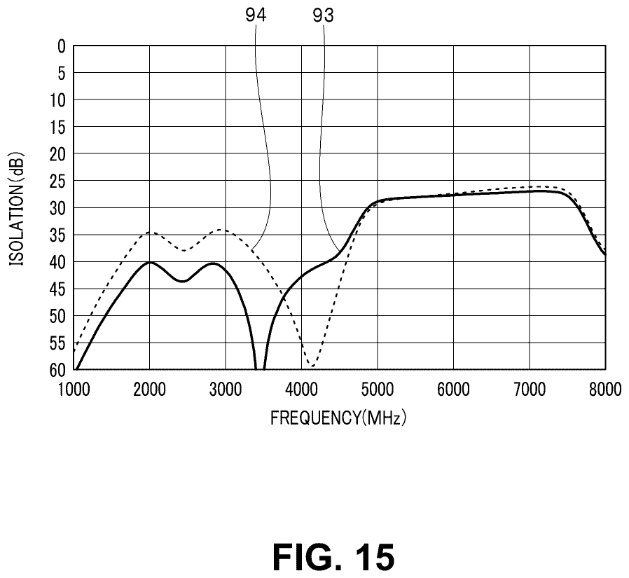

FIG. 14 is a characteristic chart showing the frequency characteristics of isolation between the first signal terminal 3 and the third signal terminal 5. FIG. 15 is a characteristic chart showing the frequency characteristics of isolation between the second signal terminal 4 and the third signal terminal 5. In FIG. 14 and FIG. 15, the horizontal axis represents a frequency, and the vertical axis represents isolation. In FIG. 14 and FIG. 15, the curved lines denoted with the reference symbols 91 and 93 indicate frequency characteristics of isolation of the model in the example, and the curved lines denoted with the reference symbols 92 and 94 indicate frequency characteristics of isolation of the model in the comparative example.

From FIG. 14, it is understood that, in a frequency region where a frequency falls within a range from 4,900 MHz to 7,125 MHz, isolation of the model in the example is greater than isolation of the comparative example. As understood from the result, according to the exemplary embodiment, the structure body 81 can secure isolation between the filter 20 and the filter 41. Consequently, isolation between the first signal terminal 3 and the third signal terminal 5 can be increased sufficiently.

From FIG. 14, it is understood that, in a frequency region where a frequency falls within a range from 2,400 MHz to 2,500 MHz, isolation of the model in the example is greater than isolation of the comparative example. As understood from the result, according to the exemplary embodiment, the structure body 82 can secure isolation between the filter 30 and the filter 41. Consequently, isolation between the second signal terminal 4 and the third signal terminal 5 can be increased sufficiently.

Next, other effects of the exemplary embodiment are described. As shown in FIG. 1, the inductor L31 is connected to the ground. In the exemplary embodiment, the inductor L31 is connected to the structure body 82 connected to the ground. With this, according to the exemplary embodiment, the number of conductors of the stack 50 can be reduced as compared to a case in which the inductor L31 is not connected to the structure body 82 but to the ground. As a result, according to the exemplary embodiment, the branching filter 1 can be reduced in size.

In the exemplary embodiment, the conductor layer for forming an element different from the inductor L31 is also connected to the structure body 82. With this, according to the exemplary embodiment, the number of conductors of the stack 50 can be reduced as compared to a case in which an element other than the inductor L31 is not connected to the structure body 82 but to the ground. As a result, according to the exemplary embodiment, the branching filter 1 can be reduced in size.

Description regarding the inductor L31 and the structure body 82 given above is applicable to the inductor L42 and the structure body 81.

In the exemplary embodiment, a part of the inductor L42 overlaps with the structure body 81 as viewed in the stacking direction T. With this, according to the exemplary embodiment, the branching filter 1 can be reduced in size as compared to a case in which the inductor L42 does not overlap with the structure body 81 as viewed in the stacking direction T.

In the exemplary embodiment, a part of the inductor L41 overlaps with the inductor L43 as viewed in the stacking direction T. With this, according to the exemplary embodiment, the branching filter 1 can be reduced in size as compared to a case in which the inductor L41 does not overlap with the inductor L43 as viewed in the stacking direction T.

Note that the disclosure is not limited to the foregoing example embodiments, and various modifications may be made thereto. For example, the multilayered branching filter of the disclosure is not limited to a triplexer, and may be a branching filter such as a diplexer and a quadplexer.

The structure body 81 may be arranged in the first region R1, or may be arranged to overlap with the boundary between the first region R1 and the second region R2. Similarly, the structure body 82 may be arranged in the second region R2, or may be arranged to overlap with the boundary between the second region R2 and the third region R3.

As described above, a multilayered branching filter according to one embodiment of the disclosure includes a common terminal, a first signal terminal, a second signal terminal, a first path connecting the common terminal and the first signal terminal to each other, a second path connecting the common terminal and the second signal terminal to each other, a first inductor provided between the common terminal and the second signal terminal in a circuit configuration, and a stack for integrating the common terminal, the first signal terminal, the second signal terminal, the first path, the second path, and the first inductor, the stack including a plurality of dielectric layers being stacked. The first path is configured to selectively cause a signal having a frequency within a first passband to pass. The second path is configured to selectively cause a signal having a frequency within a second passband to pass, the second passband being different from the first passband.

The stack further includes a first region and a second region that are adjacent within the stack, and includes a first structure body that is arranged in a vicinity of a boundary between the first region and the second region and is connected to a ground. The first structure body includes a plurality of first sub structure bodies that are stacked in a direction parallel to a stacking direction of the plurality of dielectric layers. Each of the plurality of first sub structure bodies includes a plurality of first through holes and a first conductor layer that connects the plurality of first through holes. The first inductor is arranged in the second region, and is connected to the first structure body.

The multilayered branching filter according to the aspect of the disclosure may further include a first filter provided to the first path, and a second filter provided to the second path. The first filter may be arranged in the first region. The second filter may include the first inductor, and may be arranged in the second region. Both the first filter and the second filter may be high-pass filters. Alternatively, the first filter may be a low-pass filter, and the second filter may be a high-pass filter.

The multilayered branching filter according to the aspect of the disclosure may further include a third signal terminal, a third path connecting the common terminal and the third signal terminal to each other, and a second inductor provided between the common terminal and the third signal terminal in the circuit configuration. The third path may be configured to selectively cause a signal having a frequency within a third passband to pass, the third passband being different from each of the first passband and the second passband. The stack may further include a third region adjacent to the second region within the stack, and may include a second structure body that is arranged in a vicinity of a boundary between the second region and the third region and is connected to the ground. The second structure body may include a plurality of second sub structure bodies that are stacked in the direction parallel to the stacking direction. Each of the plurality of second sub structure bodies may include a plurality of second through holes and a second conductor layer that connects the plurality of second through holes. The second inductor may be arranged in the third region, and may be connected to the second structure body.

When the multilayered branching filter according to the aspect of the disclosure includes the third path and the second inductor, and the stack includes the third region, the multilayered branching filter according to the aspect of the disclosure may further include a first filter provided to the first path, a second filter provided to the second path, and a third filter provided to the third path. The first filter may be arranged in the first region. The second filter may include the first inductor, and may be arranged in the second region. The third filter may include the second inductor, and may be arranged in the third region. The first filter may be a low-pass filter. The second filter and the third filter may be high-pass filters.

In the multilayered branching filter according to the aspect of the disclosure, the first structure body may be connected to a specific conductor layer for forming an element different from the first inductor. The first structure body may include a first end and a second end that are positioned on opposite sides in the stacking direction. The specific conductor layer may be connected to the first structure body between the first end and the second end. The specific conductor layer may include a capacitor conductor layer for forming a capacitor. The first structure body may be arranged in the second region. The specific conductor layer may extend from the first structure body to the first region.

In the multilayered branching filter according to the aspect of the disclosure, a part of the first inductor may overlap with the first structure body as viewed in the stacking direction.

In the multilayered branching filter according to the aspect of the disclosure, the first inductor may include an inductor conductor layer. The plurality of first sub structure bodies may include a specific first sub structure body positioned at an end in one direction parallel to the stacking direction. The inductor conductor layer and the first conductor layer of the specific sub structure body may be arranged at the same position in the stacking direction.

The multilayered branching filter according to the aspect of the disclosure may further include another inductor provided between the common terminal and the first signal terminal in the circuit configuration. Such another inductor may be arranged in the first region.

In the multilayered branching filter of the disclosure, the stack includes the first structure body that is arranged in the vicinity of the boundary of the first region and the second region, and is connected to the ground. The first inductor is arranged in the second region, and is connected to the first structure body. With this, according to the disclosure, isolation between the first region and the second region can be secured.

It is apparent that the disclosure can be carried out in various forms and modifications in the light of the foregoing descriptions. Accordingly, within the scope of the following claims and equivalents thereof, the disclosure can be carried out in forms other than the foregoing example embodiments.

1. A multilayered branching filter comprising:
a common terminal;
a first signal terminal;
a second signal terminal;
a first path connecting the common terminal and the first signal terminal to each other;
a second path connecting the common terminal and the second signal terminal to each other;
a first inductor provided between the common terminal and the second signal terminal in a circuit configuration; and
a stack for integrating the common terminal, the first signal terminal, the second signal terminal, the first path, the second path, and the first inductor, the stack including a plurality of dielectric layers being stacked, wherein
the first path is configured to selectively cause a signal having a frequency within a first passband to pass,
the second path is configured to selectively cause a signal having a frequency within a second passband to pass, the second passband being differ ent from the first passband,
the stack further includes a first region and a second region that are adjacent within the stack, and includes a first structure body that is arranged in a vicinity of a boundary between the first region and the second region and is connected to a ground,
the first structure body includes a plurality of first sub structure bodies that are stacked in a direction parallel to a stacking direction of the plurality of dielectric layers,
each of the plurality of first sub structure bodies includes a plurality of first through holes and a first conductor layer that connects the plurality of first through holes, and
the first inductor is arranged in the second region, and is connect ed to the first structure body.

2. The multilayered branching filter according to claim 1, further comprising:
a first filter provided to the first path; and
a second filter provided to the second path, wherein
the first filter is arranged in the first region, and
the second filter includes the first inductor, and is arranged in the second region.

3. The multilayered branching filter according to claim 2, wherein both the first filter and the second filter are high-pass filters.

4. The multilayered branching filter according to claim 2, wherein
the first filter is a low-pass filter, and
the second filter is a high-pass filter.

5. The multilayered branching filter according to claim 1, further comprising:
a third signal terminal;
a third path connecting the common terminal and the third signal terminal to each other; and
a second inductor provided between the common terminal and the third signal terminal in the circuit configuration, wherein
the third path is configured to selectively cause a signal having a frequency within a third passband to pass, the third passband being different from each of the first passband and the second passband,
the stack further includes a third region adjacent to the second region within the stack, and includes a second structure body that is arranged in a vicinity of a boundary between the second region and the third region and is connected to the ground,
the second structure body includes a plurality of second sub structure bodies that are stacked in the direction parallel to the stacking direction,
each of the plurality of second sub structure bodies includes a plurality of second through holes and a second conductor layer that connects the plurality of second through holes, and
the second inductor is arranged in the third region, and is connected to the second structure body.

6. The multilayered branching filter according to claim 5, further comprising:
a first filter provided to the first path;
a second filter provided to the second path; and
a third filter provided to the third path, wherein
the first filter is arranged in the first region,
the second filter includes the first inductor, and is arranged in the second region, and
the third filter includes the second inductor, and is arranged in the third region.

7. The multilayered branching filter according to claim 6, wherein
the first filter is a low-pass filter, and
the second filter and the third filter are high-pass filters.

8. The multilayered branching filter according to claim 1, wherein the first structure body is connected to a specific conductor layer for forming an element different from the first inductor.

9. The multilayered branching filter according to claim 8,
the first structure body includes a first end and a second end that are positioned on opposite sides in the stacking direction, and
the specific conductor layer is connected to the first structure body between the first end and the second end.

10. The multilayered branching filter according to claim 8, wherein the specific conductor layer includes a capacitor conductor layer for forming a capacitor.

11. The multilayered branching filter according to claim 8, wherein
the first structure body is arranged in the second region, and
the specific conductor layer extends from the first structure body to the first region.

12. The multilayered branching filter according to claim 1, wherein a part of the first inductor overlaps with the first structure body as viewed in the stacking direction.

13. The multilayered branching filter according to claim 1, wherein
the first inductor includes an inductor conductor layer,
the plurality of first sub structure bodies include a specific first sub structure body positioned at an end in one direction parallel to the stacking direction, and
the inductor conductor layer and the first conductor layer of the specific sub structure body are arranged at the same position in the stacking direction.

14. The multilayered branching filter according to claim 1, further comprising:
another inductor provided between the common terminal and the first signal terminal in the circuit configuration, and
the other inductor is arranged in the first region.
